(19) United States
(12) Patent Application Publication
(10) Pub. No.: US 2006/0263961 A1
(43) Pub. Date: Nov. 23, 2006

(54) Method for Forming Dual Fully Silicided Gates and Devices with Dual Fully Silicided Gates

(75) Inventors: Jorge Adrian Kittl, Waterloo (BE); Anne Lauwers, Aartselaar (BE); Anabela Veloso, Leuven (BE); Anil Kottantharayil, Leuven (BE); Marcus Johannes Henricus van Dal, Leuven (BE)

Correspondence Address: MCDONNELL BOEHNEN HULBERT & BERGHOFF LLP, 300 S. WACKER DRIVE, 32ND FLOOR, CHICAGO, IL, 60606, US

(73) Assignees: Interuniversitair Microelektronica Centrum (IMEC), Leuven (BE); Koninklijke Phillips Electronics, Eindhoven (NL); Texas Instruments Incorporated, Dallas, TX (US)

(21) Appl. No.: 11/382,986

(22) Filed: May 12, 2006

Related U.S. Application Data
(60) Provisional application No. 60/681,831, filed on May 16, 2005.
(60) Provisional application No. 60/699,179, filed on Jul. 14, 2005.

(30) Foreign Application Priority Data
Nov. 17, 2005 (JP) JP 333128 2005

(51) Int. Cl. H01L 21/8238

(52) U.S. Cl. 438/199

(57) ABSTRACT

A method for manufacturing CMOS devices with fully silicided (FUSI) gates is described. A metallic gate electrode of an NMOS transistor and a metallic gate electrode of a pMOS transistor have a different work function. The work function of each transistor type is determined by selecting a thickness of a corresponding semiconductor gate electrode and a thermal budget of a first thermal step such that, during silicidation, different silicide phases are obtained on the nMOS and the pMOS transistors. The work function of each type of transistor can be adjusted by selectively doping the semiconductor material prior to the formation of the silicide.

### CROSS-REFERENCE TO RELATED APPLICATIONS

This application is related to U.S. Provisional Application Ser. No. 60/681,831, filed May 16, 2005, and is related to U.S. Provisional Application Ser. No. 60/699,179, filed Jul. 14, 2005, and is related to Japanese Patent Application Serial Number 333128 2005, filed Nov. 17, 2005, all of which are incorporated herein by reference.

### FIELD OF THE INVENTION

The present invention relates to semiconductor process technology and devices. In particular, the present invention relates to semiconductor devices with metallic gate electrodes formed by a reaction between a metal and a semiconductor material.

### BACKGROUND

CMOS (Complementary Metal-Oxide-Silicon) devices comprise two types of transistors NMOS and pMOS, each transistor type having its own characteristics and properties. There is a trend to replace the semiconductor gate electrode with metal ones, as metal gate electrodes offer the advantages of reducing the sheet resistance, eliminating the semiconductor gate depletion effect, and controlling the work function independently from the doping of the junction regions.

Metal gate electrodes can be formed by full silicidation (FUSI) of the semiconductor gate electrode with a metal. The semiconductor gate electrode may be a polysilicon gate electrode. The metal may be a refractory metal such as W, noble metals such as Pt, near noble metals such as Ni, transition metals such as Ti, or any combination thereof. During this silicidation process, the gate electrode is converted into a silicide.

If high performing CMOS devices are to be obtained, the gate electrode work function should be different for each transistor type. Hence, a different gate electrode metal should be used for each transistor type yielding so-called dual metal gate or dual work function metal gate CMOS devices. Various manufacturing methods exist to form such dual metal gate CMOS devices using full silicidation of the semiconductor gate electrode. According to U.S. Pat. No. 6,905,922, the FUSI gate electrode of NMOS and pMOS transistors respectively should be formed in separate silicidation steps. Although this approach allows different metals to be used for each transistor type, the number of process steps will increase and the first formed silicide will be subjected to the high temperature processing of the later formed silicide.

A. Veloso et al. discloses in “Work function engineering by FUSI and its impact on the performance and reliability of oxynitride and Hf-silicate based MOSFET's, in IEDM proceedings, 2004, p855-858, the formation of fully silicided nMOS and pMOS transistors by depositing a single layer of nickel and forming a nickel-silicide by one or two annealing steps. The work function of the gate electrode can be engineered by doping the polysilicon gate prior to the deposition of the nickel layer. However, this method only allows tuning the work function for gate electrodes formed on oxynitride gate dielectrics.

US Patent Application Publication No. 2005/0158996 discloses a method for forming a thermal stable Ni₁Si₁ on a substrate, e.g., source/drain junctions or a polysilicon gate to form a low resistive path on these junction regions (source/drain).

W. Maszara et al. discloses in “Transistors with Dual Work Function Metal Gates by Single Full Silicidation (FUSI) of Polysilicon gates” in IEDM proceedings, 2002, p367-370, an alternative method to control the work function of a fully silicided gate electrode. According to this approach the FUSI gate of NMOS and pMOS transistors is formed during a single silicidation step using nickel as metal for both types of transistors. Due to the presence of dopants in the polysilicon gate electrode a different work function is obtained for nMOS and pMOS transistors respectively. Although this approach uses only one metal, the difference in work function between nMOS and pMOS transistors is determined by the dopants present in the semiconductor gate electrode prior to silicidation. Typically, the gate electrode is doped while doping the junction regions, which means that the work function of the formed transistor depends on the doping of its junction regions. If the doping of the gate electrode is to be selected independent from doping of the junction regions, additional masking and implantation steps are to be included in the process flow resulting in increased process costs and complexity.

Takahashi et al. discloses in “Dual Workfunction Ni-Silicide/HfSiON Gate Stacks by Phase-Controlled Full-silicidation (PC-FUSI) technique for 45 nm-node LSTP and LOP devices,” in IEDM proceedings, 2004, p91-94, another dual metal gate alternative. According to this approach, different phases of nickel silicide having different work functions are obtained by depositing on nMOS transistors and pMOS transistors respectively a thin and thick layer of nickel. During the subsequent annealing step the fully nickel-silicided gate electrodes should be formed having the corresponding phase. However the inventors found that, when applying the full silicidation technique of Takashi, a nickel-rich fully silicided gate electrode was obtained not only on pMOS transistors, but also on all transistors having small dimensions, including NMOS transistors with small gate lengths.

Hence, there is need for a low complexity method for manufacturing dual metal gate CMOS devices in which the work function of the metal gate electrode of each transistor type can be engineered in an easy, efficient, and controllable way, independent of the geometry and/or dimensions of the transistor or of the gate dielectric used.

### SUMMARY

The present invention relates to a method of manufacturing a dual fully-silicided-gate device, comprising providing at least two MOSFET devices each having a semiconductor gate electrode with a different thickness, depositing a metal layer, with a constant thickness, over each of the semiconductor gate electrodes, performing a thermal process, wherein each semiconductor thickness is selected such that the semiconductor gate electrode is fully silicided, whereby the at least two MOSFET devices have a different work function.

The method can further comprise the dual fully-silicided-gate device being a CMOS device, the MOSFET with the thicker semiconductor gate electrode being an nMOSFET, and the MOSFET with the thinner semiconductor gate electrode being a pMOSFET.

In a method according to the invention, the thermal process can comprise a first thermal process step to partially silicide the thicker semiconductor gate electrode, a step of removing the remaining, unreacted metal layer, a second thermal process step to fully silicide the thicker semiconductor gate electrode.

The first and/or second thermal process step(s) is/are preferably Rapid Thermal Processing (RTP) step(s).

The temperature and time parameters of the first and/or second thermal step(s) can be determined for each silicide phase by establishing a silicidation kinetics graph, such as the Ni₂Si silicidation kinetics graph shown as FIG. 5.

A method according to the invention can further comprise the silicide formed during (or resulting from) the first thermal step being a metal-rich silicide.

A method according to the invention can further comprise the metal-to-semiconductor atomic percentage ratio of the fully silicided gate electrode formed after the second thermal step being lower than the metal-to-semiconductor atomic percentage ratio of the partially silicided gate electrode formed after the first thermal step.

In particular, and having regard to the thicker semiconductor gate electrode, the silicide resulting from the first thermal process step may be metal-richer than the silicide resulting from the second thermal process step.

More particularly, a metal-rich silicide may be formed after the first thermal step.

For example a NiₓSi_{y} silicide with x/y≧2 (more particularly with 2≦x/y≦3) is formed after the first thermal step. A fully silicided gate electrode can thus be formed after the second thermal step having, at least adjacent the gate dielectric (at the interface), a NiₓSi_{y} phase with 0<x/y≦1, preferably with x/y=1 (or with x/y substantially equal to one).

A method of manufacturing a dual fully-silicided-gate device according to the invention can comprise the steps of providing a first MOSFET having a first semiconductor gate electrode with a thickness t_{Si1}; providing a second MOSFET having a second semiconductor gate electrode with a thickness t_{Si2}, wherein t_{Si2}<t_{Si1}; depositing a first metal layer having a thickness t_{M1} on the first semiconductor gate electrode of the first MOSFET; depositing a second metal layer having a thickness t_{M2} on the second semiconductor gate electrode of the second MOSFET; performing a first thermal process step to partially silicide the first semiconductor gate of the first MOSFET to form a silicide Mₓ₁S_{y1} and to fully silicide the second semiconductor gate of the second MOSFET to form a silicide Mₓ₂S_{y2}, removing the remaining, unreacted metal, and performing a second thermal process step to fully silicide the first semiconductor gate of the first MOSFET to form a silicide Mₓ₃S_{y3}.

Preferably, in a method according to the invention, x₂/y₂ is greater than x₃/y₃.

In a method of the invention the first thermal process step can comprise the steps of selecting a (suitable) thermal budget to partially silicide the first gate electrode of the first MOSFET and to fully silicide the second gate electrode of the second MOSFET.

Preferably, the first metal layer and the second metal layer have (substantially) the same composition and thickness (t_{M2}≈t_{M1}).

Preferably, the silicide (phase) resulting from the first thermal process step is (substantially) the same for the first MOSFET and for the second MOSFET (i.e. x₁/y₁≈x₂/y₂).

A method according to the invention can further comprise the thickness ratios t_{M1}/t_{Si1} and t_{M2}/t_{Si2} being selected such that the metal-to-semiconductor atomic percentage ratio (of a combined metal layer/semiconductor gate electrode), after the first thermal process step, is greater than one for the first MOSFET and greater than two for the second MOSFET.

More particularly, the metal-to-semiconductor atomic percentage ratio of the partially silicided first gate electrode of the first MOSFET is greater than one and less than two.

In a method for manufacturing a dual fully-silicided-gate device according to the invention, at least two MOSFET devices are provided, each device having a semiconductor gate electrode.

The thickness of the semiconductor gate electrode is different for each of the at least two MOSFETs, such that a thickness of the semiconductor gate electrode for one of the at least two MOSFETs is greater than a thickness of another of the at least two MOSFETs.

The method also includes depositing a metal layer at least on the semiconductor gate electrodes; performing a first thermal process step to partially silicide the thicker semiconductor gate electrode of one of the at least two MOSFETs and to fully silicide the thinner semiconductor gate electrode of one of the at least two MOSFETs; selectively removing an unreacted fraction of the deposited metal; and performing a second thermal process step to fully silicide the partially silicided semiconductor gate electrode.

A method according to the invention is particularly useful for forming a dual fully-silicided-gate CMOS device in which the MOSFET with the thicker semiconductor gate electrode is a nMOSFET and the MOSFET with the thinner semiconductor gate electrode is a pMOSFET.

In a method according to the invention, during the first thermal step, a metal-rich silicide is formed for both nMOSFET and pMOSFET, although only a part of the semiconductor gate electrode of the nMOSFET is silicided.

During the second thermal step, the partial silicided gate electrode of the nMOSFET is fully silicided. A metal-to-semiconductor atomic percentage ratio of this fully silicided gate electrode is lower than a metal-to-semiconductor atomic percentage ratio of the starting partially silicided gate electrode.

In one example, the semiconductor gate electrode comprises silicon and the metal layer comprises nickel. The metal-rich silicide formed during the first thermal step is an NiₓSi_{y} silicide with x/y≧2 (more particularly with 2≦x/y≦3). The silicide of the fully silicided gate electrode formed during the second thermal step is a NiₓSi_{y} silicide with 0<x/y≦1, preferably with x/y=1 (or with x/y substantially equal to one).

A method for manufacturing a dual fully-silicided-gate device according to the invention can also be described as follows. The method includes providing a first MOSFET having a first semiconductor gate electrode with thickness t_{Si1} and providing a second MOSFET having a second semiconductor gate electrode with thickness t_{Si2}. The thicknesses have the following relationship: t_{Si2}<t_{Si1}.

The method also includes depositing a first metal layer having a thickness t_{M1} on the semiconductor gate electrode of the first MOSFET; depositing a second metal layer having a thickness t_{M2} on the semiconductor gate electrode of the second MOSFET; performing a first thermal process step to partially silicide the first semiconductor gate of the first MOSFET to form a silicide Mₓ₁S_{y1}; and to fully silicide the second semiconductor gate of the second MOSFET to form a silicide Mₓ₂S_{y2}; selectively removing an unreacted fraction of the deposited metal; and performing a second thermal process step to fully silicide the partially silicided first semiconductor gate electrode to form a silicide Mₓ₃S_{y3}.

For the first MOSFET, a metal-to-semiconductor atomic percentage ratio of the silicide formed during the first thermal step x₂/y₂ is larger than then a metal-to-semiconductor atomic percentage ratio of the silicide formed during the second thermal step x₃/y₃. A thermal budget of the first thermal step is selected to partially silicide the gate electrode of the first MOSFET and to fully silicide the gate electrode of the second MOSFET.

In one embodiment the first and second metal layer have substantially the same composition and thickness: t_{M2}≈t_{M1} and, during the first thermal step, substantially the same silicide is formed for the first and second MOSFET such that the metal-to-semiconductor atomic percentage ratio of the silicides formed is substantially the same: x₁/y₁≈x₂/y₂.

Preferably, the metal-to-semiconductor atomic percentage ratio of the silicides formed during the first thermal step is larger than one: x₁/y₁≈x₂/y₂>1. Preferably, the metal-to-semiconductor atomic percentage ratio of the silicide of the first MOSFET formed during the first thermal step is larger than two: x₂/y₂>2. Preferably, the metal-to-semiconductor atomic percentage ratio of the silicide of the first MOSFET formed during the second thermal step is about one: x₃/y₃≈1.

Preferably, the thickness ratios t_{M1}/t_{Si1} and t_{M2}/t_{Si2} of the unreacted metal layer and of semiconductor gate electrode are selected such that the metal-to-semiconductor atomic percentage ratio of the combined metal layer/semiconductor gate electrode is greater than one for the first MOSFET and greater than two for the second MOSFET. After silicidation, the metal-to-semiconductor atomic percentage ratio of the partially silicided gate electrode of the first MOSFET is greater than one and less than two.

In one embodiment the semiconductor gate electrode of the first and second MOSFET comprises silicon and the first and the second metal layer comprises nickel.

These as well as other aspects and advantages will become apparent to those of ordinary skill in the art by reading the following detailed description, with reference where appropriate to the accompanying drawings.

### BRIEF DESCRIPTION OF THE DRAWINGS

Exemplary embodiments are illustrated in referenced figures of the drawings. It is intended that the embodiments and figures disclosed herein be considered illustrative rather than restrictive. Same numerals are used to refer to corresponding features in the drawings.

FIG. 1a is a graph that shows a variation in workfunction Φm (eV) with the thickness ratio tNi/tSi of the nickel/silicon layers before silicidation, for nickel silicide layer formed on a hafnium-silicon-oxynitride dielectric for large devices.

FIG. 1b is a graph that shows a variation in work function WF (eV) of several nickel silicides formed either on a silicon-oxide (SiO2) dielectric layer or on a hafnium-silicon-oxynitride (HfSiON) dielectric layer. The nickel silicides differ in the atomic percentage of nickel present.

FIGS. 2a-d are cross sections that show various steps of a process flow, according to an example.

FIG. 3a-e are cross sections that show various steps of a process flow, according to another example.

FIGS. 4a-d are cross sections that show various steps of a process flow, according to another example.

FIG. 5 is a graph that shows Ni₂Si silicidation kinetics, according to an example.

FIG. 6 is a graph that shows silicide growth rates for NiSi and Ni₂Si, according to an example.

FIGS. 7a-b are graphs that show a process window for a first thermal process step, according to an example.

FIGS. 8a-e are cross sections that shows various steps of a process flow, according to an example.

FIG. 9 is a graph that shows XRD (Cu K_{α} radiation) characterization of Ni silicide films as function of RPT1 temperature according to an example.

FIG. 10 is a graph that shows the reacted nickel to silicon ratio of Ni silicide films as function of the RPT1 temperature according to an example.

FIG. 11 is a graph that shows nickel silicide phase formation as function of the temperature of the first anneal step and of the thickness of the polysilicon layer according to an example.

FIGS. 12a-b are graphs that show as function of the gate length for NMOS and pMOS transistors the influence of the nickel silicide phase on a) the threshold voltage and b) on the drive current (I_{d}sat) and on the off-current (leakage at drain junction: I_{off}) according to an example.

FIG. 13 is a graph that shows the work function (WF) and threshold voltage (Vₜlin) of a pMOS transistor as function of the atomic percentage nickel in the fully silicided nickel silicide gate electrode according to an example.

### DETAILED DESCRIPTION

For selected metal-semiconductor alloys, i.e. silicides, the work function thereof may depend on the specific phase in which the alloy is formed. Hence, the suitability of such metal-semiconductor combinations as a gate electrode for one type of transistor depends on which phase of this combination can be formed for this type of transistor. The specific phase is to be formed at least at the bottom part of the gate electrode, the last few nanometers of the gate electrode (e.g. the last nanometer, or the last 2, 3, 4, 5, 10 nanometers or even more), i.e. at least at the part which is the nearest to the gate dielectric, also referred to in the present invention as the “interface”.

In other words, in the context of the present invention, the term “interface”, when referring to the silicide phase of the gate electrode, refers to the bottom part of the gate electrode (which is the nearest to the gate dielectric), of few nanometers thickness, e.g. between about 1 nm and about 10 nm, preferably between about 1 nm and about 5 nm.

In a method according to the invention, the metal layer can be of any metal(s), preferably capable of diffusing into the underlying semiconductor material, suitable for metal gate electrodes.

More particularly, the metal layer can comprise a refractory metal such as tantalum (Ta) or tungsten (W), a noble metal such as Platinum (Pt), a near noble metal such as Nickel (Ni), a transition metal such as Titanium(Ti), or any combination of two or more of these metals.

A semiconductor layer can be of any material(s) suitable for metal gate electrodes. More particularly, the semiconductor layer can comprise Silicon (Si), Germanium (Ge) or a mixture thereof.

For example, and in particular at least at the interface, metal-rich phases such as Ni₂Si, Ni₃Si₂, Ni₃₁Si₁₂, or Ni₃Si may be more suitable as FUSI gate electrode material for pMOS transistors, while metal-poor phases such as NiSi or NiSi₂ may be more suitable as FUSI gate electrode material for NMOS.

In the framework of the present invention, the terms “silicide”, “silicided”, “silicidation” can refer to the reaction between a metal and silicon, but is not intended to be limited to silicon. For instance, the reaction of a metal with Ge, or any other suitable semiconductor material, may still be referred to as silicidation.

In the framework of the present invention, the term “metal-rich silicide” refers to the material resulting from the reaction between the metal and the semiconductor, wherein the metal-to-semiconductor ratio is larger than one.

The silicide phase (also referred to as metal-semiconductor phase) can be represented by the formula MₓS_{y}, wherein M represents the metal, S represents the semiconductor, and wherein x and y are integers or real numbers different from zero. In a metal-rich silicide, x/y is larger than one.

More particularly, having regard to nickel silicide, for metal-rich phases such as Ni₂Si, Ni₃Si₂, Ni₃₁Si₁₂, or Ni₃Si, the ratio x/y is greater than one and preferably less than or equal to three (i.e. 1<x/y≦3), while for metal-poor phases such as NiSi or NiSi₂, the ratio x/y is greater than zero and less than or equal to one (i.e. 0<x/y≦1).

It is possible to obtain a specific silicide phase for a specific type of transistor by selecting for each type of transistor a thickness ratio t_{M}/t_{Si} of metal and semiconductor material present prior to the silicidation process when sufficient thermal budget is provided to drive the reaction to completion. In the approach explored by Takahashi et al in “Dual Workfunction Ni-Silicide/HfSiON Gate Stacks by Phase-Controlled Full-silicidation (PC-FUSI) technique for 45 nm-node LSTP and LOP devices”, in IEDM proceedings, 2004, p91-94, the thickness of the metal film was used to select the thickness ratio t_{M}/t_{Si} and hence the silicide phase to be formed. This has the disadvantage that an accurate control of the thickness of the nickel layer formed is needed in order to obtain the desired thickness ratio. Even if a well-controlled nickel layer would be formed, for transistors with small dimensions, the effective nickel-to-silicon ratio would be more than the one determined on the layer thickness ratio given above, as excess nickel, originating from regions adjacent such small gate electrode, will diffuse towards the polysilicon gate electrode during the thermal process step and add to the effective nickel amount available during silicidation.

The present invention discloses in a first embodiment a method to form a fully silicided gate electrode for both NMOS and pMOS transistors using one metal layer, but wherein the thickness of the semiconductor gate electrode prior to the deposition of this metal layer is different for NMOS and pMOS transistors. For the same amount of metal deposited on the semiconductor gate electrode of each type of transistor on the same wafer, different phases can be formed for each transistor type depending on the amount of semiconductor material available at the gate electrode: the less semiconductor material present, the more metal-rich the silicide will be.

Therefore, by selecting the amount of the semiconductor material of the gate electrode for each type of transistor, e.g. by selecting the thickness of the semiconductor gate electrode, different silicide phases of the metal-semiconductor combination may be formed, at least at the interface, during the same silicidation process, hence, creating two gate electrodes having a different work function in one silicidation process.

The thickness (t_{M}) of the metal present for each type of transistor can also be different (t_{M1}, t_{M2}), as long as for each type of transistor the metal-semiconductor atomic percentage ratio is such as to form the respective phases, at least at the interface, for each type of transistor.

In order to obtain a high thickness ratio t_{M}/t_{Si} for one type of transistor the amount of semiconductor material available on the corresponding gate electrode is reduced allowing a thinner layer of metal to be used. Consequently, less excess metal will be present near the other transistor type where a low thickness ratio t_{M}/t_{Si} is desired. Especially, for transistors having smaller lengths or widths, the volume of metal surrounding the gate electrode, in comparison with the volume of metal present upon the gate electrode, i.e. on top of the semiconductor gate electrode, is preferably monitored in case thicker layers of metal are used.

For the purpose of teaching the invention, nickel (Ni) is used as metal and silicon (Si) as semiconductor material. The capability of tuning the work function of FUSI gate electrodes by forming different Ni-silicide phases, at least at the interface, for each type of transistor is very attractive for CMOS integration. To achieve this, the effective nickel to silicon atomic ratio as expressed e.g. by the thickness ratio t_{Ni}/t_{Si} of the nickel/silicon layers before silicidation is preferably different for NMOS and for pMOS transistors.

If a NiSi gate electrode is to be formed for nMOS transistors, then the thickness ratio t_{Ni}/t_{Si} should be less than 1.1 and is preferably between 0.55 and 0.8.

If a Ni-rich gate electrode is to be formed for pMOS transistors, then the thickness ratio t_{Ni}/t_{Si} is preferably larger than 1.1.

For Ni/Si thickness ratios of 0.6, 0.9, 1.2, 1.4, and 1.7 respectively the NiSi, Ni₃Si₂, Ni₂Si, Ni₃₁Si₁₂, and Ni₃Si phase can be obtained at the interface between the gate electrode and the gate dielectric.

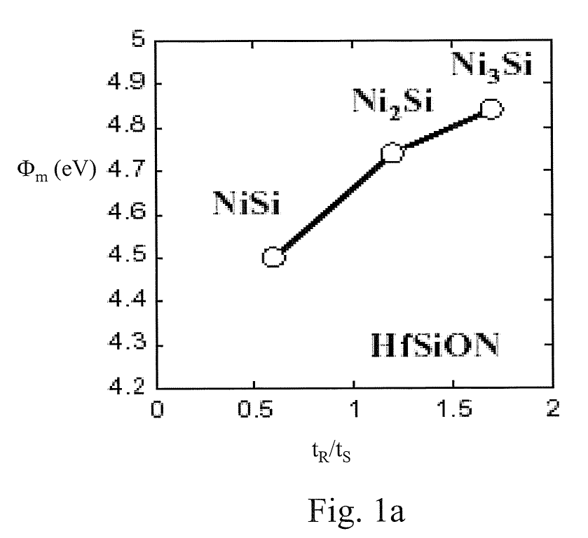

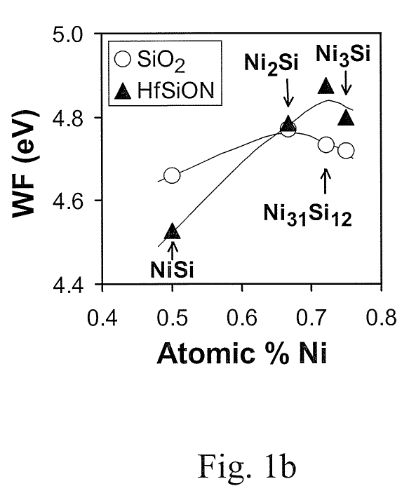

As shown in FIGS. 1a and 1b, the work function (WF)(Φm) of the silicon/nickel combination increases with increasing thickness ratio or in other words with increasing nickel content: about 4.5 eV for NiSi, about 4.74 eV for Ni₂Si, and about 4.86 eV for Ni₃Si.

A method of manufacturing a dual fully-silicided-gate device is provided, comprising the steps of: (i) providing at least two MOSFET devices each having a semiconductor gate electrode with a different thickness (the semiconductor gate electrode being formed on a gate dielectric), (ii) depositing a metal layer, with a constant thickness (t_{M}) (i.e. same thickness), over each of the semiconductor gate electrode, and (iii) performing a thermal process, preferably Rapid Thermal Processing (RTP), wherein each semiconductor thickness (T_{Si}) is selected such that the semiconductor gate electrode is fully silicided, whereby the at least two MOSFET devices have a different work function.

This method is of particular use to control the semiconductor-metal phase formed as gate electrode, at least at the interface, for large devices.

For small devices, i.e. typically smaller than 100 nm, the effective metal-to-semiconductor ratio might be larger than expected from the thickness ratio t_{M}/t_{Si}. In large devices, substantially all of the metal participating in the silicidation process stems from the metal layer above the gate electrode, whereas in small devices, a relevant amount of the metal (e.g. 10% or more, or 25% or more) originates from metal outside the area of the gate electrode. This relevant amount is sufficient to form the next metal rich phase than the one envisaged based on the thickness ratio.

In a preferred embodiment the present invention therefore combines the teaching of the first embodiment with the use of a two-step silicidation process.

In other words, according to a preferred method of the invention, the thermal process comprises a first thermal process step and a second thermal process step.

The two-step silicidation process of the present invention comprises depositing a layer of metal over the exposed semiconductor gate electrode, performing a first thermal process step, selectively removing unreacted metal, and performing a second thermal process step.

A method of manufacturing a dual fully-silicided-gate device according to the invention, comprises the steps of: (i) providing at least two MOSFET devices each having a semiconductor gate electrode with a different thickness formed on a gate dielectric, (ii) depositing a metal layer, with a constant thickness, over each of the semiconductor gate electrode, (iii) performing a first thermal process step to partially silicide the thicker semiconductor gate electrode and to fully silicide the thinner semiconductor gate electrode, wherein the silicide formed has a metal-to-semiconductor ratio larger than one, (iv) removing the remaining, unreacted metal layer, and (v) performing a second thermal process step to fully silicide the thicker semiconductor gate electrode, whereby the at least two MOSFET devices have a different work function.

In particular, where the metal is Ni and the semiconductor Si, the two-step silicidation process of the present invention comprises depositing a layer of nickel over the exposed silicon gate electrode, performing a first thermal process step, selectively removing unreacted nickel, and performing a second thermal process step.

The thickness ratio t_{Ni}/t_{Si} is preferably in the range 0.54 to 3. The thickness t_{Ni} of the as-deposited nickel layer is preferably in the range 10 nm to 200 nm, while the thickness t_{Si} of the as-deposited silicon gate electrode preferably is in the range of 20 nm to 300 nm.

The parameters of the first thermal process step are selected to form a metal (preferably Ni) rich phase on both NMOS and pMOS transistors. Due to the difference in semiconductor (preferably silicon) thickness, the semiconductor (preferably silicon) of the pMOS gate electrode is fully silicided, while the semiconductor (preferably silicon) of the NMOS gate electrode is only partially silicided such that a semiconductor (preferably silicon) layer remains between the gate dielectric and the silicided part.

Furthermore, appropriate tuning of the first thermal step assists in avoiding full silicidation of the NMOS gate electrode even for small transistors where abundant metal (preferably nickel) might be available near the gate electrode. The thermal budget of the first thermal process step is selected to fully consume the semiconductor (preferably silicon) of the pMOS transistor while the semiconductor (preferably silicon) of the NMOS transistor is only partially consumed such that enough metal (preferably nickel) is incorporated in the nMOS gate electrode, i.e. sufficient metal-rich silicide (preferably Ni-rich silicide) is formed, to allow full silicidation of this nMOS gate electrode during the second thermal process step.

In accordance with an exemplary embodiment of the invention, a thickness of the pMOS gate electrode may be less than 100 nm. Preferably, the thickness of the pMOS gate electrode may be within a range of about 20 nm to about 75 nm. Even more preferably, the thickness of the pMOS gate electrode may be within a range of about 25 nm to about 50 nm.

In accordance with an exemplary embodiment of the invention, a thickness of the NMOS gate electrode may be about 100 nm. Preferably, the thickness of the nMOS gate electrode may be within a range of about 50 nm to about 100 nm. Even more preferably, the thickness of the nMOS gate electrode may be within a range of about 50 nm to about 75 nm.

The first thermal process step can be done using Rapid Thermal Processing (RTP), in which case the temperature and duration of this first thermal process step ranges from about 240° C. to about 700° C., preferably from about 250° C. to about 675° C., more preferably from about 250° C. to about 450° C., even more preferably from about 350° C. to about 450° C., and for a time duration ranging from about 15 second to about 60 seconds. Another preferable temperature for the first thermal process step is a temperature between about 350° C. and about 675° C. for a time duration of about 15 to 60 seconds.

Other sources of thermal energy are also known in the art, such as spike annealing, laser annealing, and furnace annealing.

Preferably, a selective etch is performed to remove unreacted nickel selectively with respect to the silicide. In particular any excess metal present near the nMOS transistor will also be removed during this removal step.

Thereafter, the second thermal process step is performed to convert the remaining semiconductor (preferably silicon) of the nMOS gate electrode, thereby forming a metal-poor fully silicide (preferably a Ni-poor fully silicide) gate electrode, more particularly at least at the interface.

The silicide of the pMOS gate electrode is unaffected during the second thermal process step since no semiconductor (preferably silicon) is left for further reaction with the metal (preferably nickel).

The second thermal process step can be done using Rapid Thermal Processing (RTP), in which case the temperature and duration of this second thermal process step typically ranges from about 350° C. to about 700° C. and from about 15 sec. to about 60 sec.

Other sources of thermal energy are also known in the art, such as spike anneal, laser anneal, and furnace anneal.

In order to manufacture CMOS devices, a thickness of the semiconductor layer (preferably polysilicon layer), a thickness of the metal layer (preferably nickel layer), and the thermal budget, e.g., time and temperature of the first thermal step, are selected such that during the first thermal step, the gate electrode of the pMOS transistor (4) is fully silicided, with the selected metal-rich phase at least at the gate interface, while the gate electrode of the nMOS transistor (3) is only partially silicided.

The as-deposited metal/semiconductor (preferably nickel/silicon) ratio of the pMOS devices is greater than the as-deposited metal/semiconductor (preferably nickel/silicon) ratio of the nMOS devices by reducing (e.g. etching back) the semiconductor layer (preferably poly-Si) thickness of the pMOS devices (4) relative to the semiconductor layer (preferably poly-Si) thickness of the NMOS devices (3).

The parameters of the second thermal step are selected to fully silicide the partially silicided gate electrode of the nMOS device (3), obtaining the selected metal-poor silicide, at least at the interface.

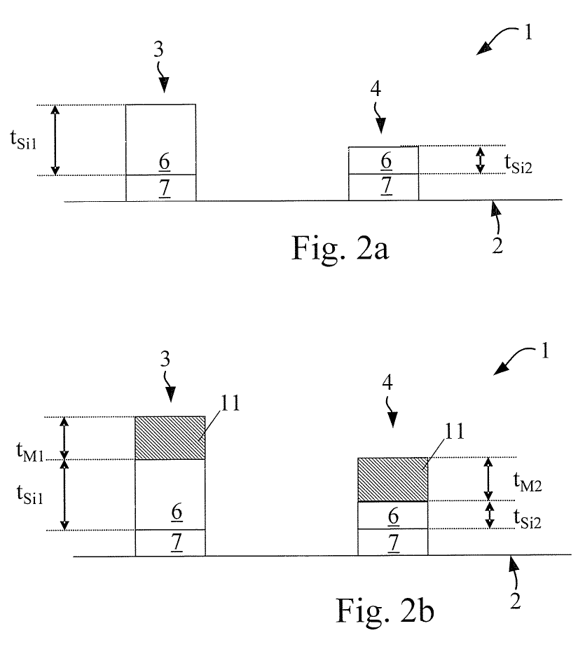

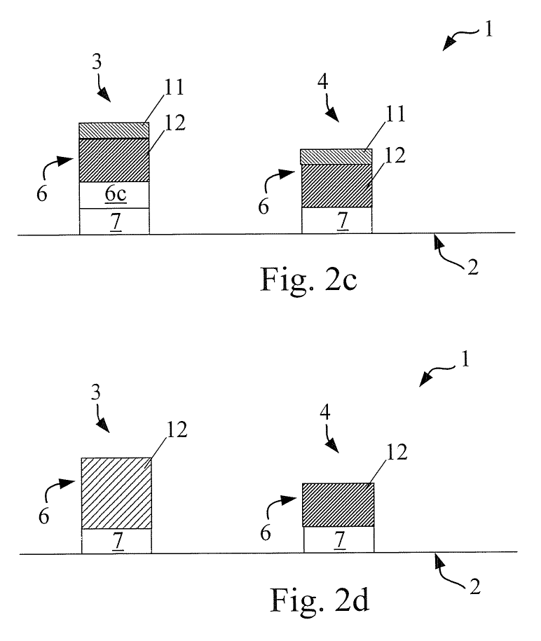

FIGS. 2a-d illustrate the above process sequence. FIG. 2a shows the gate stacks of two transistors (3, 4). Each gate stack comprises a semiconductor gate electrode (6) and a gate dielectric (7) formed on the same substrate (2). A thickness (t_{Si1}) of the semiconductor gate electrode (6) for transistor (3) is larger than a thickness (t_{Si2}) of the semiconductor gate electrode (6) for transistor (4): t_{Si1}>t_{Si2}.

Various methods are known in the art to create topography in a semiconductor layer such that gate electrodes (6) with different thickness are formed from the same semiconductor layer. For example, U.S. Pat. No. 6,855,605 teaches a method to form removable parts in a semiconductor layer, which parts can then be removed later in the processing, thereby creating topography in the semiconductor layer.

On top of each gate electrode (6), a metal (11) is deposited having a thickness t_{M}. In this example, the metal thickness is the same (t_{M1}=t_{M2}) for both transistors (3, 4) as shown in FIG. 2b.

During the first thermal process step, a metal-rich silicide is formed, which in the case of the thin semiconductor layer (t_{Si2}) replaces this gate electrode (6), while for the thicker semiconductor layer (t_{Si1}) still a bottom part (6c) of the original semiconductor layer remains near the gate dielectric (7). As shown in FIG. 2c, some excess metal (11) can remain for transistor (3).

As shown in FIG. 2d, after selectively removing an unreacted fraction of the metal (11), the gate electrode of transistor (3) is completely silicided, thereby converting the stack of metal-rich silicide top layer and semiconductor bottom layer into a metal-poor silicide gate electrode (12).

The semiconductor gate electrode can be doped prior to silicidation to allow further tuning of its work function. For one type of silicide phase obtained, the corresponding work function can be modified by the type and amount of dopant present in the semiconductor gate electrode before fully silicidation thereof. Kedzierski et al teaches in “Metal-gate FinFET and fully depleted SOI devices using total gate silicidation”, proceedings IEDM 2002 p 247, the effect of substitution dopants on the work function of NiSI FUSI gate electrode.

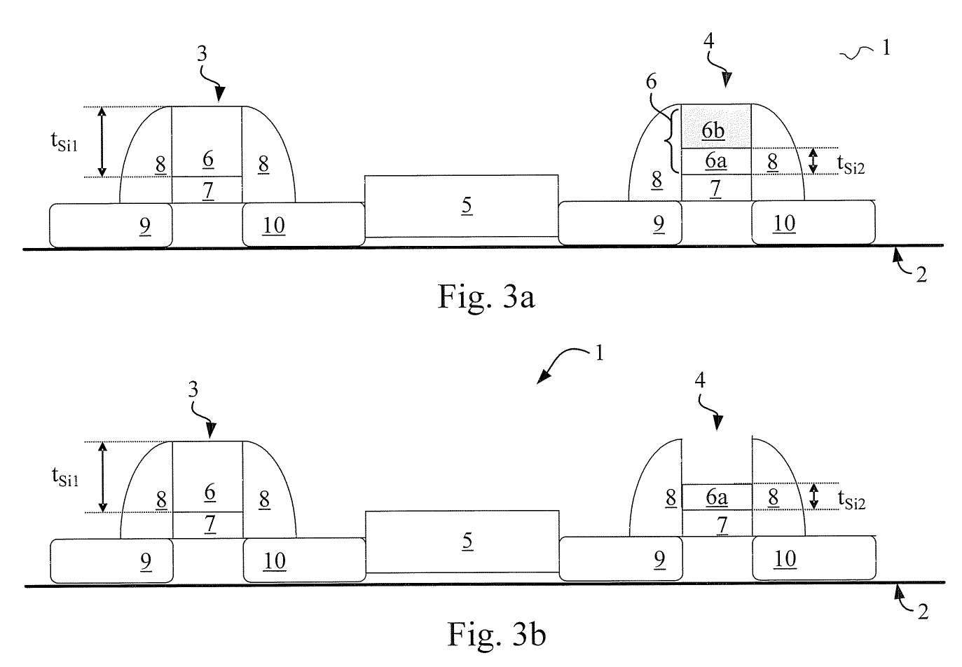

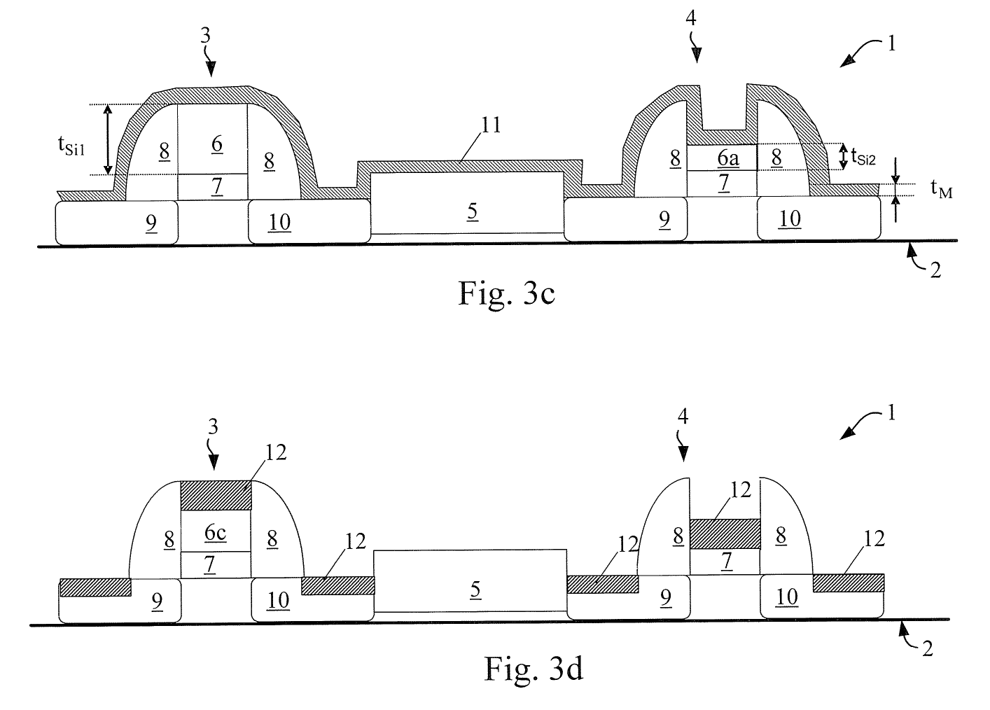

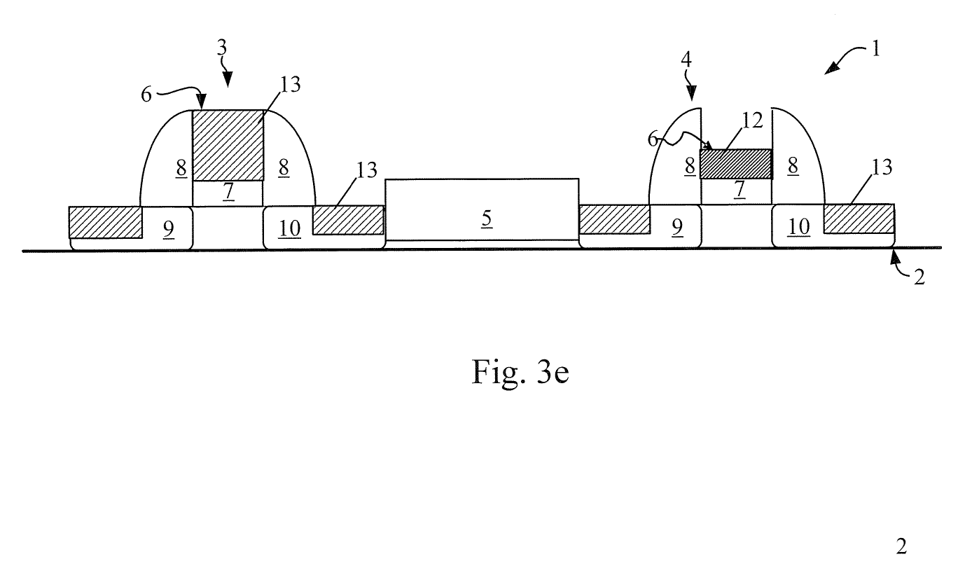

FIGS. 3a-e schematically illustrate a process flow according to an example. FIG. 3a shows a CMOS device (1) formed on a substrate (2). The CMOS device comprises at least one nMOS transistor (3) and at least one pMOS transistor (4). Each transistor comprises a gate electrode (6), a gate dielectric (7) in-between the gate electrode (6) and the substrate (2), sidewall spacers (8) formed in a dielectric material adjacent the stack of gate electrode (6) and gate dielectric (7), source (9) and drain (10) junction regions aligned to the gate stack (6, 7) and extending underneath the sidewall spacers (8). Isolation structures (5) are provided to isolate the nMOS transistor (3) from the pMOS transistor (4).

The transistors (3, 4) shown in FIG. 3a can be any type of Metal-Oxide-Semiconductor Field-Effect-Transistor (MOSFET), such as a bulk transistor or a Multiple Gate transistor (MuGFET).

The gate dielectric (7) can be a siliconoxide, a siliconoxynitride, or a high-k dielectric, such as hafniumoxides, hafniumsilicates, and alumina-oxides, as known in the art.

The gate electrode (6) is formed in a semiconductor material, such as silicon and silicon-germanium.

As shown in FIG. 3a, the gate electrode (6) of the nMOS transistor (3) is preferably formed of a single semiconductor material, such as polycrystalline silicon, having a thickness t_{Si1}, while the gate electrode (6) of the pMOS transistor (4) comprises a stack of at least two layers (6a, 6b). These at least two layers (6a, 6b) are formed in different materials, which are selected such that the exposed layer (6b) can be selectively removed.

The substrate (2) can be a bulk semiconductor substrate (e.g. silicon or germanium wafer) or a semiconductor-on-insulator substrate (e.g., Silicon-On-Insulator (SOI), or Germanium-In-Insulator (GeOI)).

The CMOS device (1) shown in FIG. 3a can be manufactured by standard semiconductor processes as known and appreciated by any person skilled in the art.

In the next process step illustrated in FIG. 3b, a top layer (6b) (e.g., a SiGe plug) of the pMOS transistor (4) is selectively removed such that a bottom semiconductor layer (6a) is exposed. Preferably, the top layer (6b) is formed from SiGe while the bottom semiconductor layer (6a) is formed from polycrystalline silicon. This material is preferably also used to form the gate electrode (6) of the NMOS transistor (3). A dry etch process may be used to remove the top layer (6b) such that the bottom semiconductor layer (6a) having the predetermined thickness t_{Si2} remains.

In the next process step illustrated in FIG. 3c, a layer of metal (11) having thickness t_{M} is uniformly deposited over the substrate. For the pMOS transistor (4) the thickness t_{M} and t_{Si2} are chosen such that the thickness ratio t_{M}/t_{Si2} is obtained corresponding with the desired silicide phase to be formed throughout the semiconductor layer (6a). For the nMOS transistor (3), the thickness t_{M} and t_{Si1} are chosen such that complete silicidation of the semiconductor layer (6) is avoided.

The CMOS device (1) is heated in a first thermal process step (e.g., Rapid Thermal Processing (RTP)), to form a metal-rich fully silicide gate electrode (12) for the pMOS transistor (4) and a metal-rich partially silicided gate electrode (12) and for the nMOS transistor (3).

Unreacted metal (11) is removed yielding the CMOS device (1) shown in FIG. 3d.

The silicidation process according to the present invention is completed by a second thermal process step (e.g., Rapid Thermal Processing (RTP)), in which the partially silicided NMOS transistor (3) gate electrode (12) becomes fully silicided.

During the first thermal step of this two-step silicidation process, a metal-rich silicide is formed on all transistors such that for transistors with a thinner semiconductor gate electrode this gate electrode becomes fully silicided, while the gate electrode of transistors with a thicker semiconductor gate electrode is only partially silicided. Such partial silicided gate electrode, hence, contains two portions: a silicided metal-rich portion adjacent the metal layer and an unsilicided semiconductor portion adjacent the gate dielectric.

The thermal budget of the first silicidation step is selected to control the amount of silicide formed in the partially silicided gate electrode. Sufficient thermal energy is provided to silicide only a portion of the semiconductor gate electrode but with sufficient metal incorporated therein.

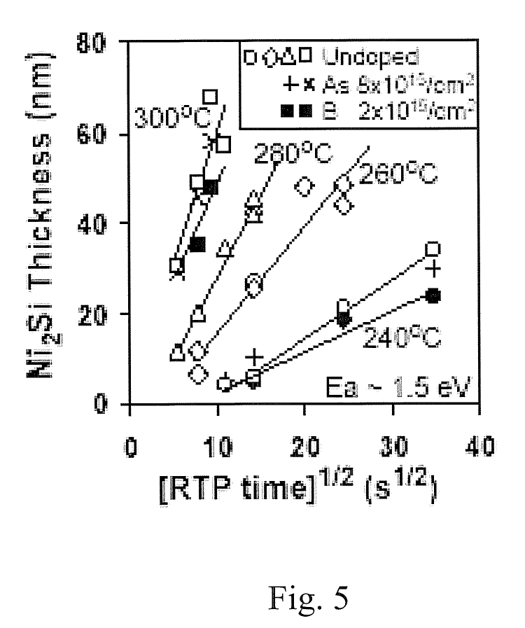

Temperature and time parameters of the first thermal step can be determined for each silicide phase by establishing a silicidation kinetics graph, such as the Ni₂Si silicidation kinetics graph drawn up and represented in FIG. 5.

During the second thermal step, the partially silicided gate electrode becomes fully silicided whereby metal from silicided metal-rich portion reacts with semiconductor material of the unsilicided portion to yield the selected silicide phase for the fully silicided gate electrode.

A semiconductor process flow, corresponding to a two-step silicidation process of the invention, has the advantage that the amount of silicide formed does not depend on the amount of metal available, but on the thermal budget of the first thermal step. Hence the thickness of the metal layer deposited is less critical thereby increasing the process window. Any excess metal is removed by a selective wet etch after the first thermal process step such that during the second thermal step only metal incorporated in the metal-rich silicided portion of the gate electrode will react.

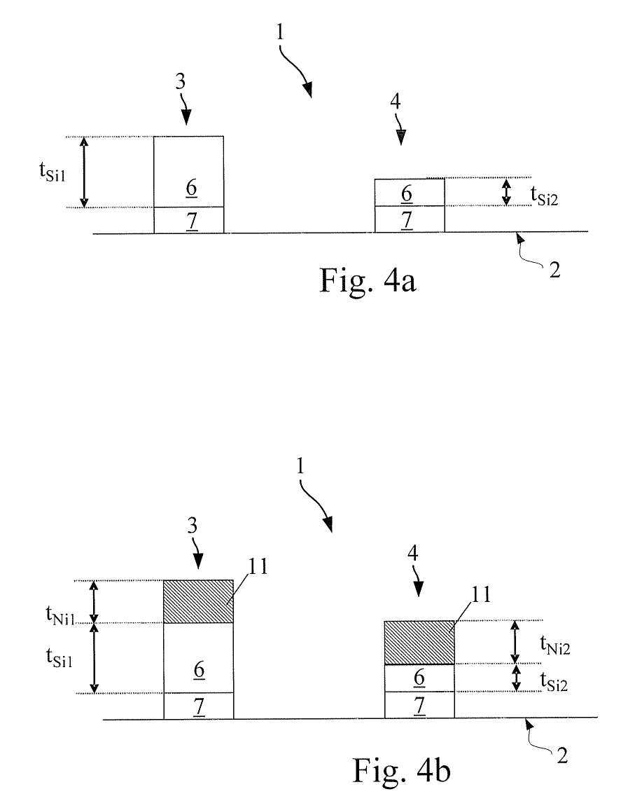

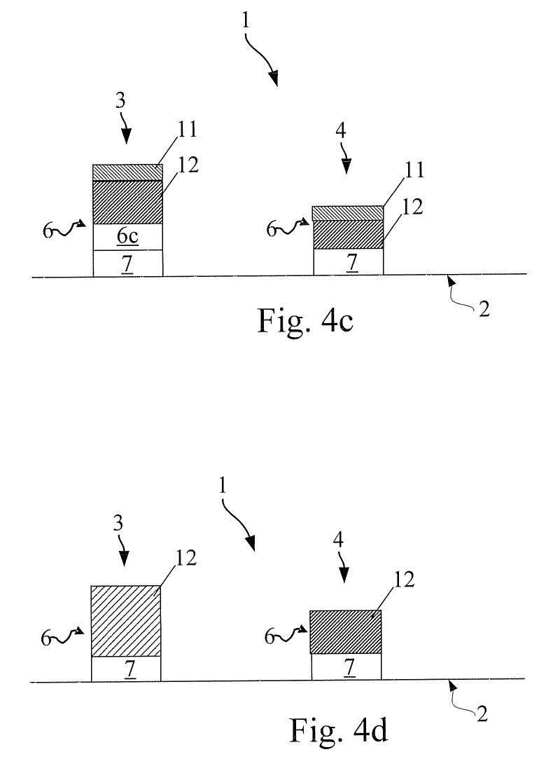

The above embodiment is illustrated by FIGS. 4a-d where transistor (3) is now a NMOS transistor for which a NiSi gate electrode (12) is to be formed and transistor (4) is now a pMOS transistor for which a metal-rich nickel silicide (e.g., Ni₂Si) gate electrode (12) is to be formed. As shown in FIG. 4a, a nMOS transistor (3) and pMOS transistor (4) are formed whereby the semiconductor gate electrode (6) is thicker for the nMOS transistor (3) then for the pMOS transistor (4): t_{Si1}>t_{Si2}.

As shown in FIG. 4b, a nickel layer (11) is deposited over the gate electrodes (6) and, in this embodiment, this nickel layer (11) has the same thickness for both types of transistors (3, 4): t_{Ni1}=t_{Ni2}. The thickness of the unreacted metal layer (11) and of the unreacted semiconductor gate electrode is selected such that a NiSi phase is formed for the fully silicided gate nMOS transistor (3) and a Ni₂Si phase is formed for the fully silicided gate pMOS transistor (4). In accordance with this exemplary embodiment, (i) t_{Ni1}/t_{Si1}>0.54, preferably at about 0.6 (nMOS), and (ii) t_{Ni2}/t_{Si2}>1.1, preferably at about 1.2 (pMOS).

These requirements can also be expressed in ratio of atomic percentage of the as-deposited layers as the aim of the first thermal step is to introduce sufficient nickel in the semiconductor gate such that for both types of transistors a nickel-rich silicide is formed. For the pMOS transistor this metal-rich silicide extends over the whole of the gate electrode, while for the NMOS transistor only a portion of the gate electrode is silicided while a uniform layer of silicon (6c) remains in the nMOS gate electrode near the gate dielectric (7):
Ni/Si (at %)>1 (nMOS);
Ni/Si (at %)>2 (pMOS).

These above relationships, either expressed in thickness or atomic percentage ratio, only define a lower limit for the amount of nickel present. Sufficient nickel must be present to form a nickel-rich silicide and any nickel in excess will be removed during the subsequent selective etch.

As shown in FIG. 4c, a first thermal process step is performed. The thermal budget of this first thermal step is selected to fully silicide the gate electrode of the pMOS transistor (4), e.g. such that the nickel-to-silicon ratio of the all nickel (12) and silicon after this first thermal step and after the selective etch, meets the relationship: Ni/Si (at %)>2.

All semiconductor material of the pMOS gate electrode is reacted with the nickel and a metal-rich silicide (12) is formed.

The thermal budget of this first thermal step is selected to only partially silicide the gate electrode of the nMOS transistor (3). In this way, only a portion of the semiconductor material of the nMOS gate electrode will react with the nickel. During a second thermal process step, a metal-rich portion will provide the nickel to react with the unsilicided portion such that an overall nickel-poor full silicided gate electrode is formed on the NMOS transistor (3).

Any nickel in excess (11) will be removed during the subsequent selective etch. The thermal budget of this first thermal step is selected such that the nickel-to-silicon ratio of the all nickel (12) and silicon, be it in the silicided portion (12) and in the unsilicided portion (6c), still present in the gate electrode of the NMOS transistor, after this first thermal step and after the selective etch, meets the relationship: 1<Ni/Si (at %)<2 (nMOS), preferably 1<Ni/Si (at %)<1.5, more preferably Ni/Si (at %) is about 1.2.

For a given thickness of polysilicon t_{Si1}, the reacted nickel and silicon ratio can be determined from the silicidation kinetics and the time-temperature dependence of the first thermal process step. FIG. 5 shows the Ni₂Si silicidation kinetics. The Ni₂Si thickness as function of time for various temperatures is given for undoped (open/unshaded symbols), As-doped (+ and − symbols) or B-doped (solid/shaded symbols). The activation energy Ea of this physical process is found to be around 1.5 eV.

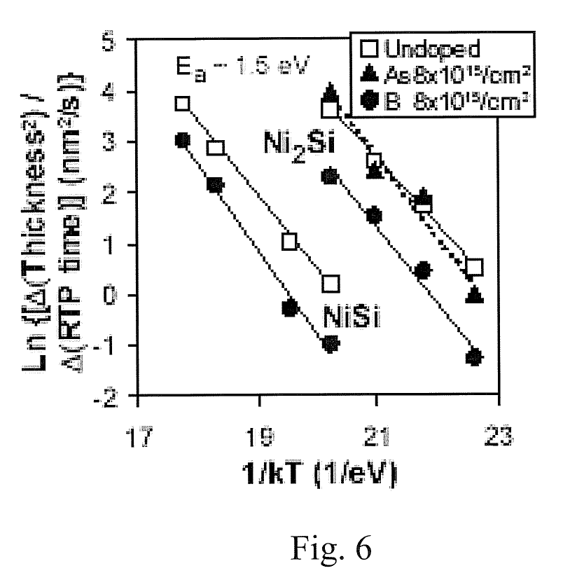

FIG. 6 shows the logarithm of the silicide growth rates for NiSi and Ni₂Si as a function of temperature T for undoped (open/unshaded squares), As-doped (solid/shaded triangles), and B-doped (solid/shaded circles) silicides. At low temperatures, e.g., at temperatures as low as about 240° C., a Ni₂Si phase will start to be formed in a process that is controlled by the diffusion of the nickel from the nickel layer (11) into the polysilicon gate electrode (6). If excess nickel is removed and only nickel from the nickel-rich silicided portion (12) is available, then NiSi will be grown at higher temperatures, e.g. at a temperature between about 350° C. and about 700° C., in a process that is controlled by the diffusion of nickel from the metal-rich portion (12) into the unsilicided portion (6c) resulting in a fully silicided NiSi gate electrode for the nMOS transistor (3). For a given thickness of polysilicon t_{Si1}, the process window for the first thermal process step can be determined using the information of FIGS. 5 and 6.

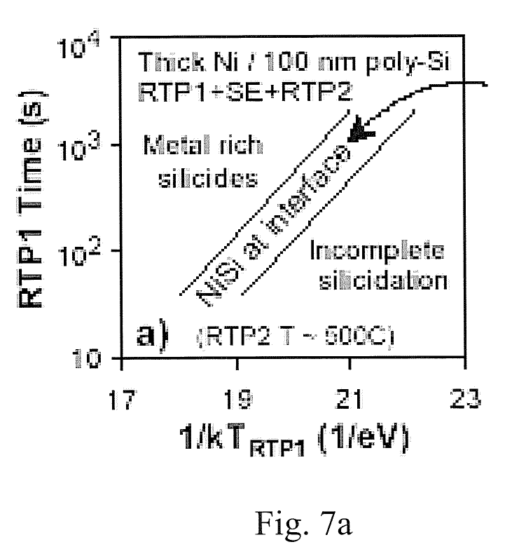

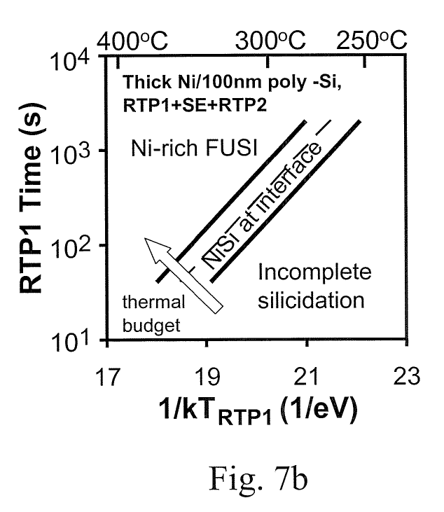

FIG. 7a and FIG. 7b show a process window of the first thermal step (dotted area). Any combination of time and temperature within the process window will result in a nickel-silicon atomic percentage ratio corresponding to a partial nickel-rich silicidation of the NMOS gate electrode after the first thermal process step and a complete silicidation of this gate electrode after the second thermal process step. The thickness of the partial silicided NMOS gate electrode is about the thickness of the fully silicided pMOS gate electrode if the same metal-rich silicide phase is formed for both types of transistors during the first thermal step.

As shown in FIG. 4d, the partially silicided nMOS gate electrode is fully silicided whereby nickel from the silicided nickel-rich portion reacts with silicon from the unsilicided portion. Due to this redistribution of the nickel, the selected nickel-to-silicon ratio, in this case NiSi, is obtained uniformly over the NMOS gate electrode (6). As no excess nickel is present, i.e. only nickel that has really been reacted, the nickel-to-silicon ratio of the pMOS gate electrode is substantially maintained and further growth of the nickel-rich portion of the partial silicided nMOS gate electrode is prevented. The thermal budget of the second thermal step is chosen such that for the NMOS device all nickel from the nickel-rich portion (12) reacts with all silicon from the gate electrode (12, 6c).

For each silicidation metal (11) and silicide phase to be formed, curves similar to the curves shown in FIGS. 5, 6, 7a, and 7b can be generated. From such curves, the growth rate of the metal-rich silicide and the process window for the thermal budget of the first thermal process step can be determined. Relationships 4-7 can be generalized as follows. If fully silicided gate electrodes with a metal-low Mₓ₃Si_{y3} (3) and a metal-rich Mₓ₂Si_{y2} (4) silicide are to be formed, the following relationships are valid:
as-deposited:
   metal/silicon (at % ratio)>x₃/y₃ (nMOS);
   metal/silicon (at % ratio)>x₂/y₂ (pMOS);
after the first thermal step and selective removal of excess metal:
x₃/y₃<metal/silicon (at % ratio)<x′₃/y′₃ (nMOS); with x′₃/y′₃ being the atomic percentage ratio of the next metal-silicon compound which is more metal rich than the compound which is to be formed, at least at the interface, e.g. NiSi: x₃/y₃=1, Ni₂Si: x′₃/y′₃=2.

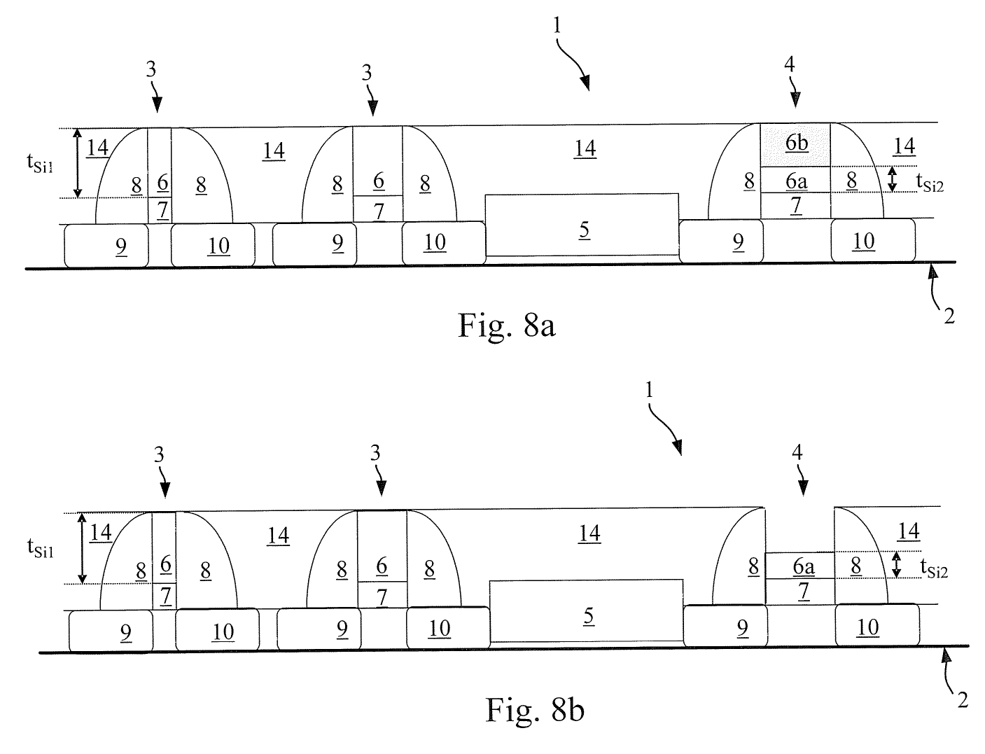

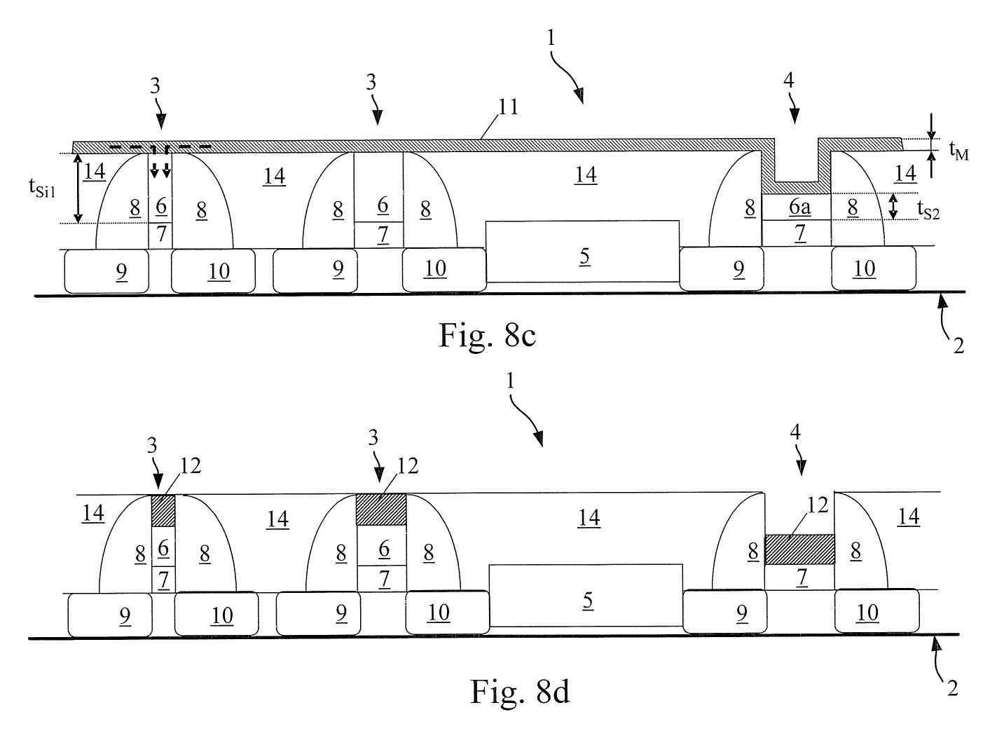

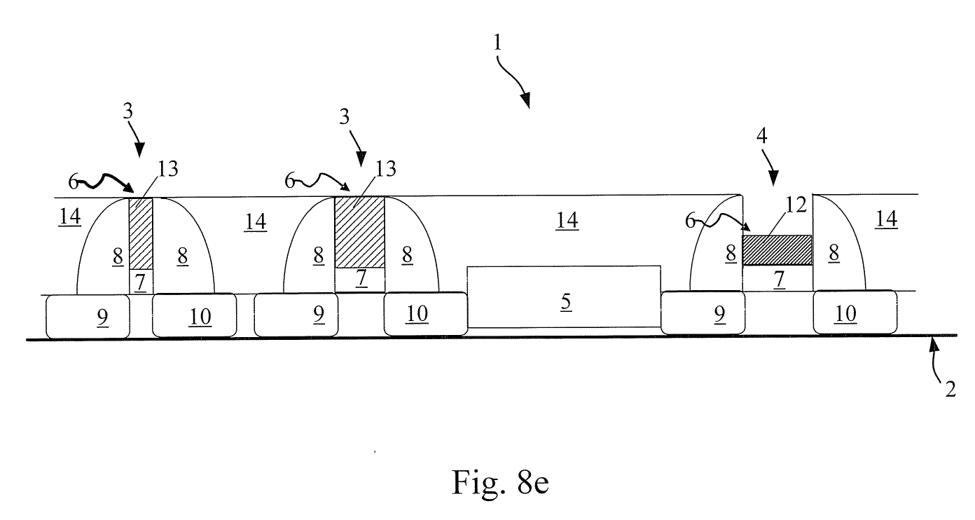

FIGS. 8a-e show the CMOS device (1) according to another example. In the example illustrated in FIGS. 8a-e, the source junction regions (9) and the drain junction regions (10) are silicided together with the gate electrodes (6). FIGS. 8a-e schematically illustrate a process flow that allows the gate electrodes (6) to be silicided independently from the source junction regions (9) and the drain junction regions (10).

In addition to the device shown in FIG. 8a, a dielectric (14) is deposited over the substrate and planarized using Chemical-Mechanical-Polishing (CMP) yielding the CMOS device (1) of FIG. 3a. Two nMOS transistors (3) are shown only differing in the length of the gate, i.e. the distance between the source junction region (9) and the drain junction region (10). The transistors (3, 4) may be formed with polysilicon as gate electrode material (6) having a thickness t_{Si1}=100 nm and HfSiON as gate dielectric (7).

The reduced height (t_{Si2}) of the polysilicon gate electrode (6) for the pMOS transistor (4) may be achieved by etching a back of the pMOS gates just before gate silicidation as shown in FIG. 8b.

In accordance with an exemplary embodiment, an additional masking step may be used to expose the gate electrode of selected transistors such that: (i) for selected pMOS transistors, the thickness of the polysilicon gate electrode is reduced such that during the two-step silicidation process a metal-rich silicide is formed, and (ii) for other pMOS transistors, the original polysilicon thickness is maintained such that a metal-poor silicide is obtained during the same two-step silicidation process.

The polysilicon thickness of the gate electrode of the pMOS transistor was reduced to 30% or 45% (t_{S2}) of the original polysilicon thickness (t_{S1}).

As another example, a single Ni film (11), shown in FIG. 8c, having a thickness t_{M}=60 nm, may be used to obtain a Ni/Si thickness ratio of t_{M}/t_{Si1}=0.6 for the nMOS transistors (3) and t_{M}/t_{Si2}=2 (30% reduction) or 1.3 (45% reduction) for the pMOS transistor (4). Simultaneous silicidation of nMOS and pMOS transistors was done in a two-step Ni FUSI process.

FIG. 8d shows the CMOS device (1) after the first thermal step, performed at 340° C. for 30 seconds, with a metal-rich (12) FUSI gate electrode (6) for the pMOS transistor (4) and a partially silicided (12/6) gate electrode (6) for both NMOS transistors (3) independent of their gate length.

FIG. 8e shows the CMOS device (1) after the second thermal step, performed at 520° C. for 30 seconds, with a FUSI gate electrode (6) for all transistors (3, 4).

From XRD analysis, the phase present in the gate electrode of the pMOS transistors (4) was identified as Ni₂Si, while a stack of Ni₂Si/NiSi was identified for the gate electrode of the nMOS transistors (3). The absence of more Ni-rich phases (e.g., Ni₃Si₂, Ni₂Si, Ni₃₁Si₁₂, and Ni₃Si) in the FUSI gate electrode of the pMOS transistor (4) is to be attributed to the low thermal budget of the first thermal step and shows that the silicidation process of this first thermal step was controlled by the predetermined thermal budget.

The sheet resistance Rs of the FUSI gate electrode is found to be about 2 Ohm/sq for the NMOS transistors (3), independent of the gate length, and about 10 Ohm/sq (45% height reduction) or about 16 Ohm/sq (30% height reduction) for the pMOS transistor (4). The sheet resistance values are consistent with the presence of mainly NiSi phase in the NMOS transistors (3) and Ni₂Si phase in the pMOS transistor (4).

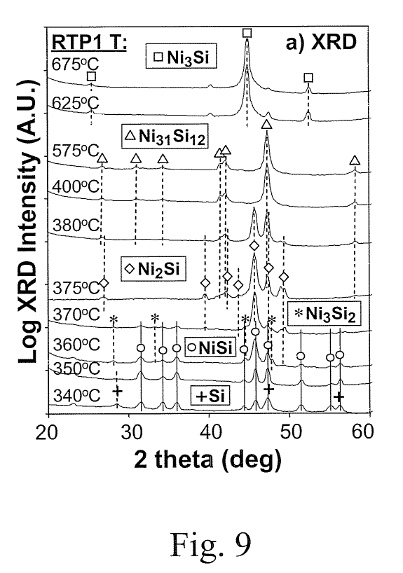

FIG. 9 shows the crystallographic characterization of silicide films manufactured using a manufacturing process as illustrated by FIGS. 2a-d.

The silicide films are characterized using X-ray Diffraction (XRD).

These fully silicided gates are obtained by depositing 170 nm of nickel on 100 nm polycrystalline silicon, such that the silicidation reaction is not limited by the supply of the refractory metal, in this example nickel.

The gate dielectric is a hafnium-silicon-oxide-nitride dielectric. The two-step thermal process is performed using an ASM Levitor RTP system.

The temperature of the first thermal step (RTP1) is varied from about 340° C. to about 675° C. The time of this first thermal step was set at about 30 seconds.

A selected etch is performed to remove unreacted nickel after the first thermal step.

Thereafter a second thermal step (RTP2) is executed at 480° C. for about 30 seconds.

It is found that when the reaction is not limited by the availability of nickel, the resulting silicide phase of a fully silicided polysilicon gate can be effectively controlled by the thermal budget of the first thermal step (RTP1).

Within the conditions set for FIG. 9 in terms of thicknesses (170 nm Ni/100 nm poly-Si) and time (30 seconds), for RTP1 temperatures less than or equal to 350° C., the polysilicon gates are not fully silicided (even if abundant nickel is present).

Poly-Si (+Si) X-ray Diffraction (XRD) peaks are observed as shown in FIG. 9. From 350° C. onwards complete silicidation of the 100 nm polysilicon gate can occur.

For RTP1 temperatures in the range of 355° C. to 375° C., XRD shows the presence of various nickel silicide phases in the fully silicided gate.

FIG. 9 illustrates the nickel silicide phases present in the fully silicided gate electrode for first thermal temperatures of respectively 360° C., 370° C. and 375° C.: NiSi (open/unshaded circles), Ni₃Si₂ (stars, i.e., * symbols) and Ni₂Si (open/unshaded diamonds) phases are formed.

Rutherford Backscattering Spectrometry (RBS) and Transmission Electron Microscopy (TEM) analysis showed that the thus-obtained fully silicided films have a layered structure with the metal-poor phase, in this case NiSi, at the bottom of the fully silicided gate electrode (6) in contact with the underlying gate dielectric (7) (i.e. at the interface), while the metal-rich silicides, in this case Ni₃Si₂ and Ni₂Si, are in the upper part of the fully silicided gate electrode.

The work function of these gate electrodes will thus be determined by the NiSi phase at the interface.

Within the conditions set for FIG. 9, the RTP1 temperature process window for forming NiSi, at least at the interface, is about 20° C. or less.

Within the conditions set for FIG. 9, the process window of the first thermal step (RTP1) for forming Ni₂Si at least adjacent the gate dielectric (7) (i.e. at least at the interface) is 25° C. or less.

If the temperature of the first thermal step (RTP1) is above 400° C., Ni₃₁Si₁₂ will start to grow. In the temperature range from about 400° C. to about 600° C. a fully silicided gate electrode will be formed during the first thermal step where essentially only a Ni₃₁Si₁₂ phase can be detected. FIG. 9 shows fully silicided gate electrodes formed respectively at RTPI temperatures of 400° C. and 575° C. only exhibiting Ni₃₁Si₁₂ XRD peaks (open/unshaded triangles).

If the temperature of the first thermal step (RTP1) is above 625° C., Ni₃Si will start to grow. In a temperature range above about 625° C. a fully silicided gate electrode will be formed during the first thermal step where essentially only a Ni₃Si phase can be detected. FIG. 9 shows fully silicided gate electrodes formed respectively at RTP1 temperatures of 625° C. and 675° C. only exhibiting Ni₃Si XRD peaks (open/unshaded squares). The RTP1 temperature process window to form Ni₃₁Si₁₂, at least at the interface, is about 200° C.

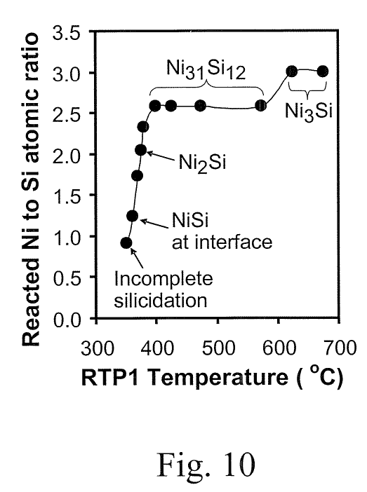

The method of controlling the phase formation for a fully silicided gate electrode is illustrated by FIG. 10 using the experimental results in relation with FIG. 9 for the example of nickel silicide.

The Ni to Si reacted ratio is controlled by the thermal budget of the first RTP step (RTP1) which thermal budget is determined by its time and temperature. In FIG. 10, the time is kept constant for 30 seconds, while the temperature of the first thermal step is varied to vary the thermal budget thereof.

At low RTP1 thermal budgets, i.e. below 350° C., insufficient Ni has reacted, at least for transistors having a large gate lengths, e.g. 100 nm or above, and the polycrystalline silicon gate electrode remains incompletely silicided even after performing a second thermal step RTP2.

In the thermal budget range associated with the RP1 temperature range 350° C. to 375° C. sufficient Ni has reacted to result in a full silicidation of the gate electrode after RTP2 with NiSi in contact with the gate dielectric (7) (i.e. at the interface) for gate lengths above and below 100 nm.

In the thermal budget range associated with the RP1 temperature range 375° C. to 400° C. sufficient Ni has reacted to result in a full silicidation of the gate electrode after RTP2 with Ni₂Si in contact with the gate dielectric (7) (i.e. at the interface) for gate lengths above and below 100 nm.

In the thermal budget range associated with the RP1 temperature range 400° C. to 600° C. sufficient Ni has reacted to result in a full silicidation of the gate electrode after RTP2 with Ni₃₁Si₁₂ in contact with the gate dielectric (7) (i.e. at the interface) for gate lengths above and below 100 nm.

In the thermal budget range associated with the RP1 temperature range above 600° C. sufficient Ni has reacted to result in a full silicidation of the gate electrode after RTP2 with Ni₃Si₁ in contact with the gate dielectric (7) (i.e. at the interface) for gate lengths above and below 100 mm.

In a particularly preferred embodiment, a CMOS device is provided comprising a NiSi FUSI gate electrode on NMOS and a Ni₂Si or a Ni₃₁Si₁₂ FUSI gate electrode on pMOS.

Ni FUSI gate CMOS circuits with HfSiON gate dielectric (1.5 nm equivalent oxide thickness, (Hf/(Hf+Si)=50 at %) can be fabricated using a CMP flow as described for example by K. G. Anil et al., “Demonstration of fully Ni-silicided metal gates on HfO₂ based high-k gate dielectrics as a candidate for low power applications,” in Symp. VLSI Tech. Dig., 2004, pp. 190-191.

The CMOS integration flow (for example FIGS. 3a-e or FIGS. 8a-e) comprises a poly-Si etch back step to reduce the height of pMOS devices before gate silicidation, and a 2-step RTP gate silicidation process performed simultaneously on nMOS and pMOS devices.

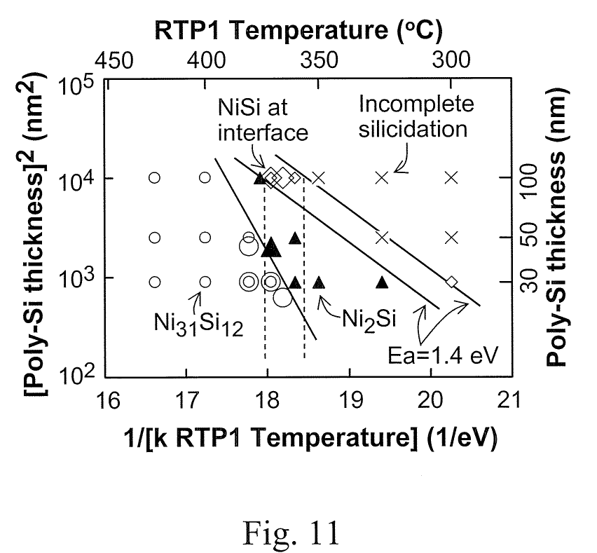

Poly-Si thickness can be 100 nm as deposited, and reduced on pMOS devices by poly-Si etch back to thicknesses in the 25 to 50 nm range. In particular, the poly-Si thickness can be reduced to about 50 nm for obtaining a Ni₂Si FUSI gate electrode on pMOS, and to about 25 to 30 nm for obtaining a Ni₃₁Si₁₂ FUSI gate electrode on pMOS (see FIG. 11).

FIG. 11 illustrates that with increasing polythickness, even if sufficient nickel is available for silicidation, the temperature of the first annealing step (RTP1) at which a selected phase is to be formed will shift to higher values if the time period of this first annealing step is kept fixed. If the temperature and time of the first annealing step is kept constant, i.e. a constant thermal budget, then incomplete silicidation is likely to occur with increasing thickness of the polysilicon layer.

Wafers can also be fabricated with deposited poly-Si thicknesses of 30 nM and 50 nm, for physical characterization.

Ni thickness for gate silicidation can be in the 60-170 nm range.

RTP silicidation steps can be performed in an ASM Levitor RTP system. The RTP1 temperatures can include temperatures between about 300° C. and about 675° C. for about 30 seconds. A selective Ni etch is then performed before the second RTP step, with an RTP2 temperature of about 480° C., for about 30 seconds.

X-ray diffraction (XRD) can be used for phase identification.

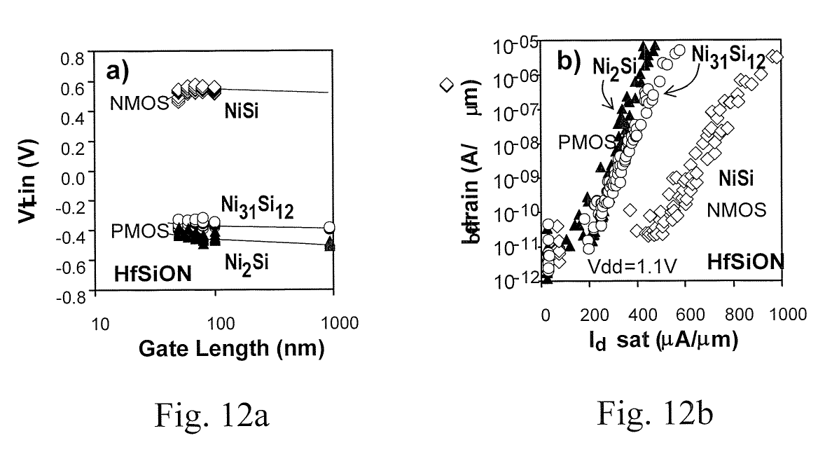

The Vₜ roll-off and Iₒₙ-I_{off} characteristics are shown in FIGS. 12a and 12b. Smooth Vt roll-off is observed for NiSi gate NMOS devices and for both Ni₂Si and Ni₃₁Si₁₂ gate pMOS devices, with ˜90 mV lower |Vt| for Ni₃₁Si₁₂ compared to Ni₂Si (FIG. 12a), in agreement with the measured difference in WF values. Improved performance is also observed for Ni₃₁Si₁₂ compared to Ni₂Si (FIG. 12b).

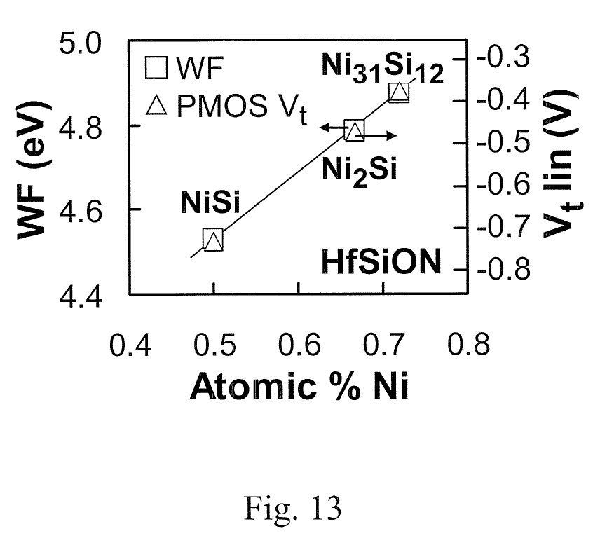

Working ring oscillators can be fabricated with NiSi nMOS gates and Ni₃₁Si₁₂ pMOS gates achieving improved performance as well. A total reduction in pMOS Vt of 350 mV is achieved by implementing the dual WF CMOS flow with Ni₃₁Si₁₂ FUSI in pMOS, when compared to a single WF flow with NiSi on nMOS and pMOS (FIG. 13).

In other words, an improvement in threshold voltage of 90 mV and improved device performance is obtained for Ni₃₁Si₁₂ compared to Ni₂Si FUSI gates. And a pMOS Vt reduction of 350 mV is obtained for Ni₃₁Si₁₂ compared to NiSi FUSI gates.

Exemplary embodiments of the present invention have been described above. Those skilled in the art will understand, however, that changes and modifications may be made to the embodiments described without departing from the true scope and spirit of the present invention, which is defined by the claims.

1. A method of manufacturing a dual fully-silicided-gate device, comprising the steps of:
providing at least two MOSFET devices each having a semiconductor gate electrode with a different thickness formed on a gate dielectric;
depositing a metal layer, with a constant thickness, over each of the semiconductor gate electrode;
performing a first thermal process step to partially silicide a thicker semiconductor gate electrode and to fully silicide a thinner semiconductor gate electrode, wherein a silicide formed has a metal-to-semiconductor ratio larger than one,
removing a remaining, unreacted metal layer; and
performing a second thermal process step to fully silicide the thicker semiconductor gate electrode,
whereby the at least two MOSFET devices have a different work function.

2. The method of claim 1, wherein the dual fully-silicided-gate device is a CMOS device, and the MOSFET with the thicker semiconductor gate electrode is an nMOSFET and the MOSFET with the thinner semiconductor gate electrode is a pMOSFET.

3. The method of claim 1, wherein a metal-to-semiconductor atomic percentage ratio of the fully silicided gate electrode formed after the second thermal process step is lower, at least at a bottom of the gate dielectric, than the metal-to-semiconductor atomic percentage ratio of the partially silicided gate electrode formed after the first thermal step.

4. The method according to claim 1, wherein each semiconductor gate electrode comprises silicon.

5. The method according to claim 1, wherein each metal layer comprises nickel.

6. The method according to claim 5,
wherein the suicide obtained after the first thermal step is a NiₓSi_{y} silicide, and
wherein x and y are integers, with 2≦x/y≦3.

7. The method according to claim 1, wherein the first thermal process step and the second thermal process step are both Rapid Thermal Processing steps.

8. The method according to claim 7, wherein the thickness of the pMOS gate electrode is less than 100 nm.

9. The method according to claim 7, wherein the thickness of the nMOS gate electrode is about 100 mm.

10. The method according to claim 9, wherein a temperature for the first thermal process step is between about 250° C. and about 675° C. for about 15 to 60 seconds.

11. The method according to claim 9, wherein a temperature for the second thermal process step is between about 350° C. and about 700° C. for about 15 to 60 seconds.

12. The method according to claim 9,
wherein a temperature for the first thermal process step is between about 350° C. and about 675° C. for about 30 seconds, and
wherein a temperature for the second thermal process step is about 480° C. for about 30 seconds.

13. A method of manufacturing a dual fully-silicided-gate device, comprising the steps of:
providing a first MOSFET having a first semiconductor gate electrode with a thickness t_{Si1};
providing a second MOSFET having a second semiconductor gate electrode with a thickness t_{Si2}, wherein t_{Si2}<t_{Si1};
depositing a first metal layer having a thickness t_{M1} on the first semiconductor gate electrode of the first MOSFET;
depositing a second metal layer having a thickness t_{M2} on the second semiconductor gate electrode of the second MOSFET;
performing a first thermal process step to partially silicide the first semiconductor gate electrode of the first MOSFET to form a silicide Mₓ₁S_{y1} and to fully silicide the second semiconductor gate electrode of the second MOSFET to form a silicide Mₓ₂S_{y2};
selectively removing an unreacted fraction of the deposited metal; and
performing a second thermal process step to fully silicide the partially silicided first semiconductor gate electrode to form a silicide Mₓ₃S_{y3}.

14. The method of claim 13, wherein x₂/y₂>X₃/y₃.

15. The method of claim 13, wherein performing the first thermal process step comprises selecting a thermal budget to partially silicide the first gate electrode of the first MOSFET and to fully silicide the second gate electrode of the second MOSFET.

16. The method of claim 13,
wherein the first and second metal layers have substantially the same composition and thickness, and
wherein during the first thermal process step substantially the same silicide is formed for the first and second MOSFETs.

17. The method according to claim 13,
wherein the first semiconductor gate electrode of the first MOSFET comprises silicon, and
wherein the second semiconductor gate electrode of the second MOSFET comprises silicon.

18. The method according to claim 13, wherein thickness ratios t_{M1}/t_{Si1} and t_{M2}/t_{Si2} are selected such that the metal-to-semiconductor atomic percentage ratio of the combined metal layer/semiconductor gate electrode is greater than one for the first MOSFET and greater than two for the second MOSFET.

19. The method according to claim 18, wherein the metal-to-semiconductor atomic percentage ratio of the partially silicided first gate electrode of the first MOSFET is greater than one and less than two.

20. The method according to claim 13, wherein the first and the second metal layers comprise nickel.

21. The method according to claim 20,
wherein x₁/y₁ is substantially equal to x₂/y₂, and
wherein x₁/y₁ is greater than one.

22. The method according to claim 21,
wherein x₂/y₂ is (i) greater than two, and (ii) less than or equal to three, and
wherein x₃/y₃ is substantially equal to one.
